(19) United States
(12) Patent Application Publication
(10) Pub. No.: US 2026/0040567 A1
(43) Pub. Date: Feb. 5, 2026

(54) MEMORY DEVICE INCLUDING CAPACITIVE SENSING CIRCUIT

(71) Applicant: Micron Technology, Inc., Boise, ID (US)

(72) Inventors: Paolo Fantini, Vimercate (IT); Lorenzo Fratin, Buccinasco (IT); Paolo Tessariol, Arcore (IT)

(21) Appl. No.: 19/265,549

(22) Filed: Jul. 10, 2025

Related U.S. Application Data
(60) Provisional application No. 63/677,262, filed on Jul. 30, 2024.

(51) Int. Cl. H10B 43/40; G11C 16/26; H10B 41/41

(52) U.S. Cl. CPC H10B 43/40; G11C 16/26; H10B 41/41

(57) ABSTRACT

Some embodiments include apparatuses and methods of forming the apparatuses. One of the apparatuses includes a memory device. The memory device includes: a first conductive region; tiers of memory cells; memory cell pillars extending through the tiers of memory cells; a second conductive region coupled to the memory cell pillars and located between the first conductive region and the tiers of memory cells; semiconductor structures separated from each other and located between the first and second conductive regions, the semiconductor structures including a semiconductor structure, the semiconductor structure including a first portion, a second portion, and a third portion between the first and second portions; a first conductive contact located between and contacting the first portion of the semiconductor structure and the first conductive region; and a second conductive contact located between and contacting the second portion of the semiconductor structure and the second conductive region.

### PRIORITY APPLICATION

This application claims the benefit of priority to U.S. Provisional Application Ser. No. 63/677,262, filed Jul. 30, 2024, which is incorporated herein by reference in its entirety.

### BACKGROUND

A memory device (e.g., a flash memory device) has memory cells for storing information and data lines to carry information to and from the memory cells. The memory device also has circuitry (e.g., amplifiers and buffer circuits) that operates to determine the value of information to be stored in the memory cells in write operations of the memory device. The circuitry also operates to determine (e.g., to sense) the value of information read from the memory cells in read operations of the memory device. In a memory operation (e.g., read or write operation) performed on selected memory cells of the memory device, the value of information is based on the value of signals (e.g., voltage, current, or both) on data lines associated with the memory cells. In memory devices (e.g., vertical NAND flash memory), the value of such signals (e.g., current signals) can be relatively small (e.g., current in nanoampere range). At a certain small signal value, it can be a challenge for the circuitry to accurately sense the signal (e.g., during a read operation) and provide reliable information.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having blocks (blocks of memory cells) and respective sub-blocks sensing circuits in each of the blocks, according to some embodiments described herein.

FIG. 3A shows a detailed schematic diagram including blocks BLK0 and BLK1 and associated sensing circuits of blocks BLK0 and BLK1 of memory device of FIG. 2, according to some embodiments described herein.

FIG. 3B shows a schematic diagram of one of the sensing circuits of FIG. 3A and a portion the memory cell strings of the memory device of FIG. 3A, according to some embodiments described herein.

FIG. 4 shows a top view of a structure of a portion of the memory device of FIG. 3 including a region of a memory array, data lines extending among the blocks of the memory device, dielectric structures between the blocks, and a footprint of sensing circuits in respective blocks, according to some embodiments described herein.

FIG. 5 shows a side view (e.g., cross-section) of a structure of a portion of the memory device of FIG. 4, including tiers of materials that include respective memory cells and control gates associated with the memory cells, according to some embodiments described herein.

FIG. 6 shows top views of respective portions of the structure of the memory device of FIG. 4 and FIG. 5, including memory cell pillars and conductive lines associated with control gates of the memory device of FIG. 4, according to some embodiments described herein.

FIG. 7A, FIG. 7B, and FIG. 7C show a perspective view, a side view, and a top view, respectively, of a structure of a portion of memory device of FIG. 2 through FIG. 6 including a structure of a sensing circuit of the memory device, according to some embodiments described herein.

FIG. 8A and FIG. 8B show a perspective view and a side view, respectively, of a memory device that can be a variation of the memory device of FIG. 7A, according to some embodiments described herein.

FIG. 9 shows a top view of a portion of a memory device including memory cell pillars arranged in groups associated sensing circuits, according to some embodiments described herein.

FIG. 10A through FIG. 18 show different views of elements during processes of forming a memory device including forming conductive contacts of the memory device, according to some embodiments described herein.

### DETAILED DESCRIPTION

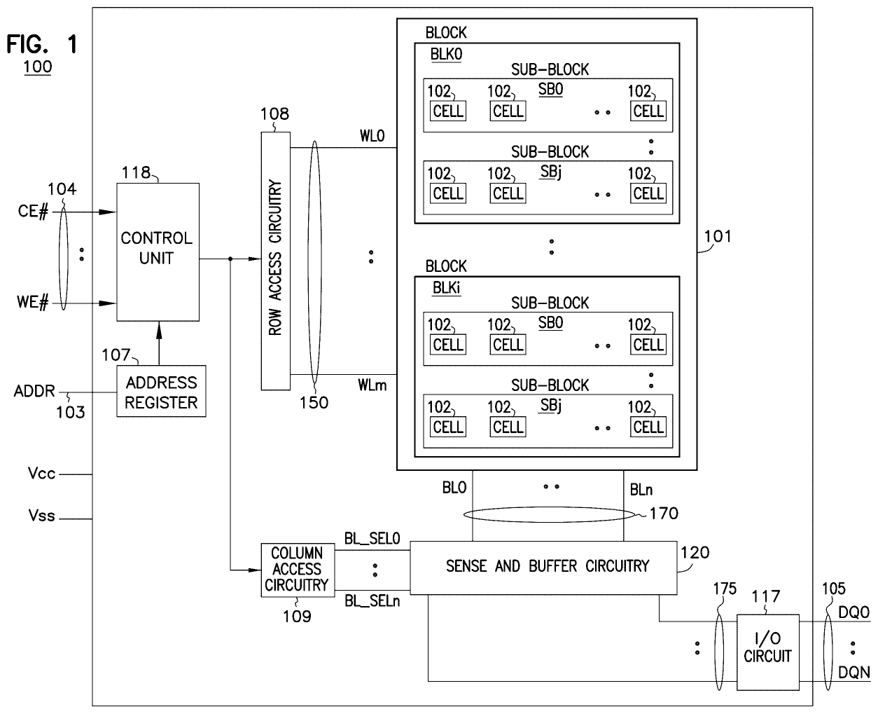

The techniques described herein involve a memory device including sensing circuits that are part of circuitry (e.g., amplifiers and buffer circuits) of the memory device. The circuitry operates to determine the value of information to be stored in or read from memory cells of the memory device. In many conventional memory devices (e.g., vertical NAND flash memory), such circuitry is usually located at a region (e.g., in a semiconductor substrate) of the memory device that is different from a memory cell array region that contains memory cells of the memory device. In the memory device described herein, the sensing circuits are located (formed) over memory cell pillars associated with tiers of memory cells in the memory array region. In an example, each sensing circuit includes semiconductor structures that formed part of respective transistors of the sensing circuit. The semiconductor structures of each sensing circuit are formed such that they occupy a relatively small portion (e.g., small piece) and small footprint (e.g., layout) of the memory cell array region. The location and structures of the sensing circuits allow them to accurately sense signals (e.g., voltage, current, or both) that may have a relatively small signal value (e.g., current in nanoampere range). This can improve performance (e.g., during a read operation) of the memory device. Other improvements and benefits of the techniques described herein are further discussed below with reference to FIG. 1 through FIG. 18.

FIG. 1 shows a block diagram of an apparatus in the form of a memory device 100, according to some embodiments described herein. Memory device 100 can include a memory array (or multiple memory arrays) 101 containing memory cells 102 arranged in blocks (blocks of memory cells), such as blocks BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines 170 can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE #, a write enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

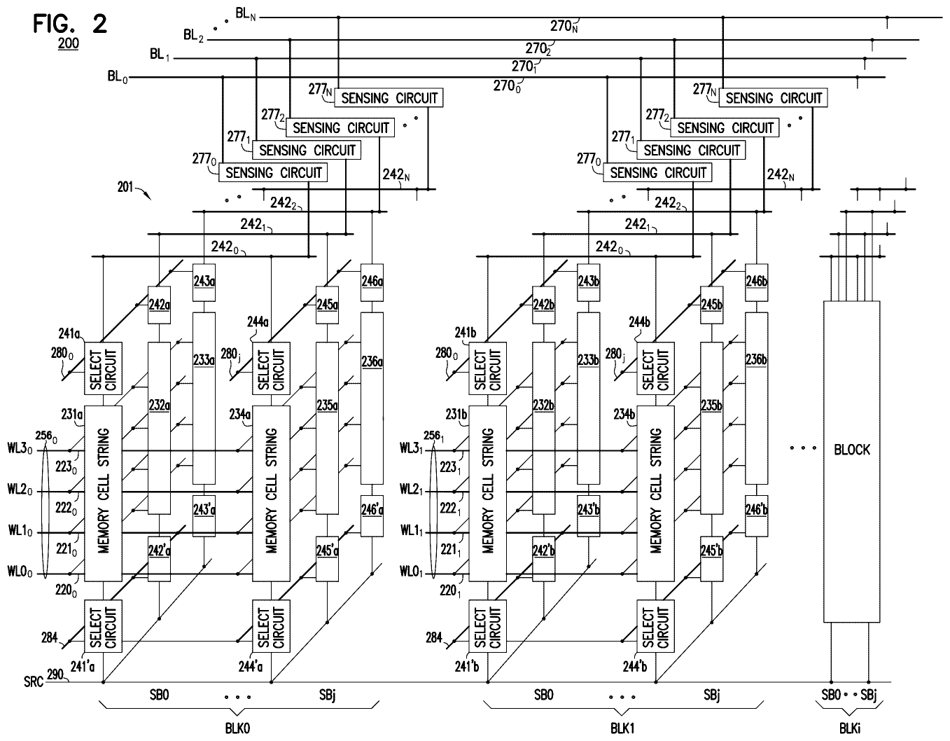

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 17B.

FIG. 2 shows a general schematic diagram of a portion of a memory device 200 including a memory array 201 having blocks (blocks of memory cells) BLK0 through BLKi, and sub-blocks SB0 through SBj and sensing circuits 277₀ through 277_{N} in respective blocks BLK0 and BLK1 in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

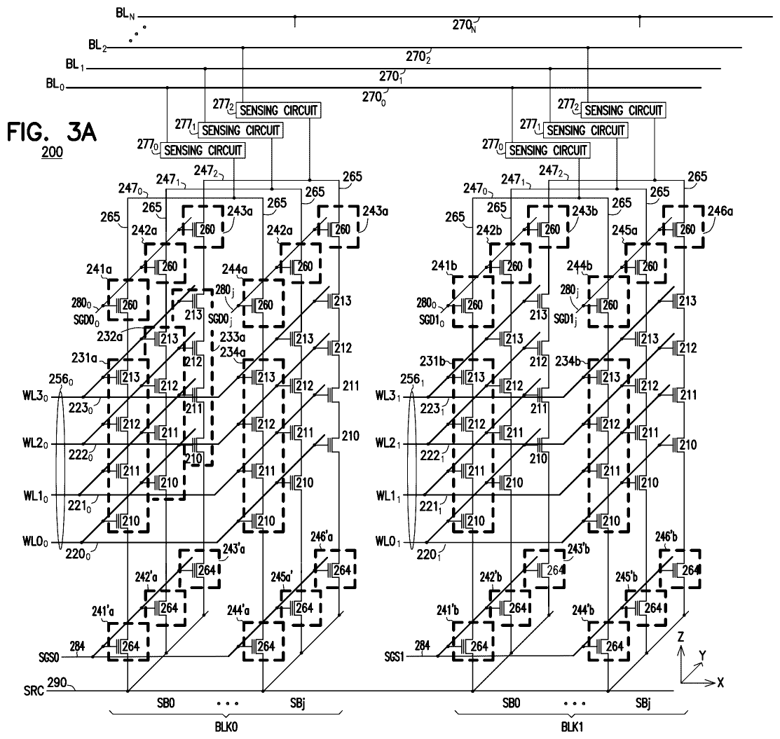

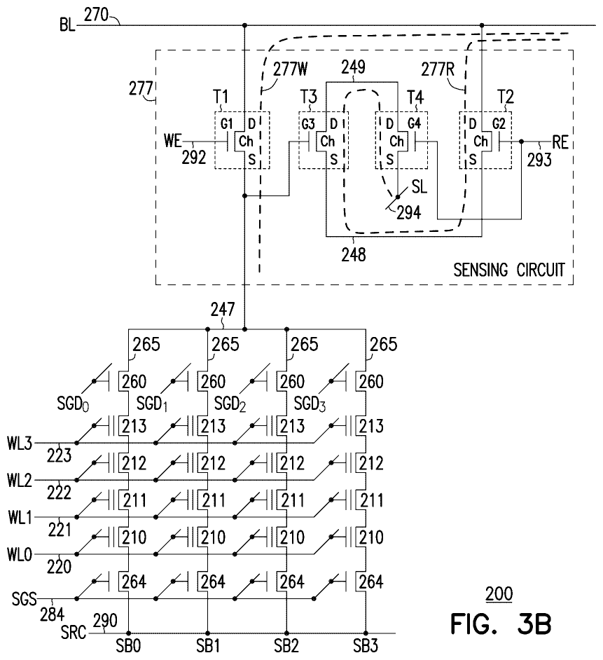

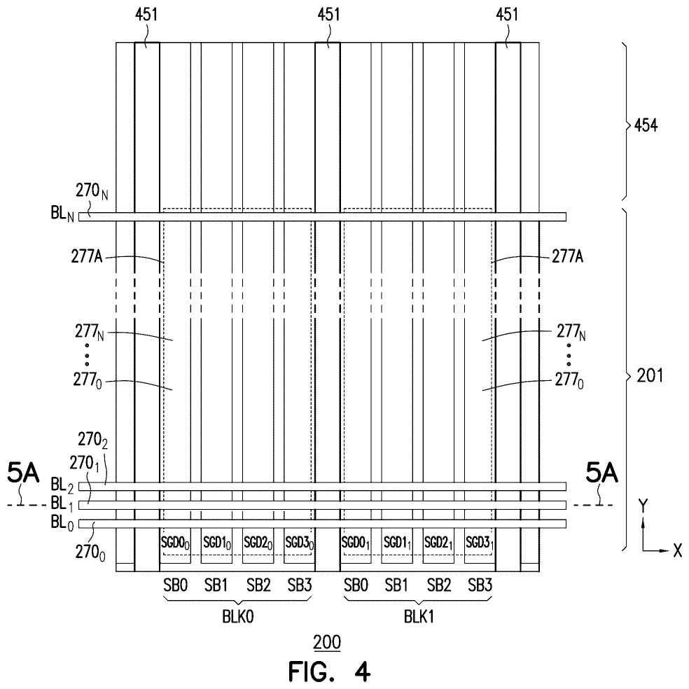

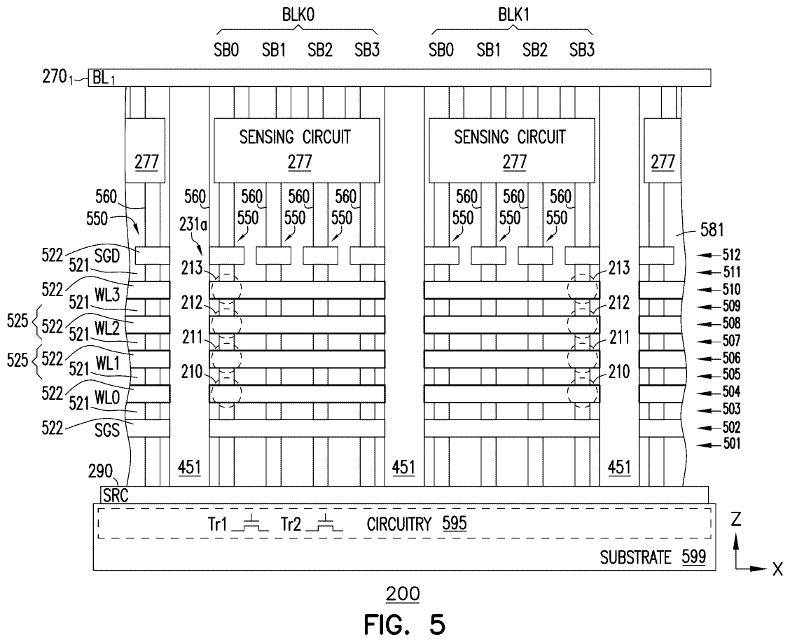

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3A and FIG. 4) and a pillar (e.g., pillar 550 in FIG. 5) where the series-connected memory cells can be located (e.g., vertically located) along a respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

Blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. Memory cell strings of different subblocks from the same block (and from different blocks) can share the same data line. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 270₁. Memory cell strings 233a, 236a (of block BLK0), 233b and 236b (of block BLK1) can share data line 270₂.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₁, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₁, 222₁, and 223₁ can be electrically separated from each other. Control gates 220₀, 221₀, 222₀, and 223₀ can be electrically separated from control gates 220₁, 221₁, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

Each of control gates 220₀, 221₀, 222₀, and 223₀ can be part of a structure (e.g., a level) of a conductive material (e.g., a layer of conductive material) located in a level of memory device 200. Control gates 220₀, 221₀, 222₀, and 223₀ can carry corresponding signals (e.g., word line signals) WL0₀, WL1₀, WL2₀, and WL3₀. Memory device 200 can use signals WL0₀, WL1₀, WL2₀, and WL3₀ to selectively control access to memory cells of block BLK0 during an operation (e.g., read, write, or erase operation).

Each of control gates 220₁, 221₁, 222₁, and 223₁ can be part of a structure (e.g., a level) of a conductive material (e.g., a layer of conductive material) located in a level of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK1 during an operation (e.g., read, write, or erase operation).

As shown in FIG. 2, in sub-block SB0 of block BLK0, memory device 200 can include a select line (e.g., drain select line) 280₀ that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 280₀. Select line 280₀ of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 280₀) shared by select circuits (e.g., select circuits 241a, 242a, or 243a) in a sub-block (e.g., sub-block SB0 of block BLK0). However, memory device 200 can include multiple drain select lines shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple source select lines shared by source select circuits in a sub-block.

In FIG. 2, each of the drain select circuits of memory device 200 can include a drain select gate (e.g., a transistor, shown in FIG. 3A) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3A) coupled between source 290 and a respective memory cell string. The source select gate (e.g., transistor) can be controlled (e.g., turned on or turned off) by a signal on a respective source select line based on a voltage provided to the signal.

As shown in FIG. 2, each of blocks BLK0 and BLK1 can includes respective sensing circuits 277₀ through 277_{N}. For simplicity, similar or the same elements in memory device 200 (in FIG. 2 and in other figures) are given the same label. For example, as shown in FIG. 2, the sensing circuits (e.g., sensing circuits 277₀ through 277_{N}) in blocks BLK0 and BLK1 are given the same labels. However, sensing circuits 277₀ through 277_{N} in blocks BLK0 and BLK1 operate at different times. For example, in a read operation associated with block BLK0, sensing circuits 277₀ through 277_{N} in block BLK0 can be activated while sensing circuits 277₀ through 277_{N} in blocks BLK1 are deactivated. In another example, in a read operation associated with block BLK1, sensing circuits 277₀ through 277_{N} in blocks BLK1 can be activated while sensing circuits 277₀ through 277_{N} in blocks BLK0 are deactivated.

In block BKL0, sensing circuits 277₀ through 277_{N} can operate as capacitive sensing circuits to provide signal amplification (e.g., pre-amplification in a read operation) associate signals from selected memory cell pillars (described below) of selected memory cell strings in selected subblocks of block BLK0. Sensing circuits 277₀ through 277_{N} in block BLK0 can provide signals (e.g., pre-amplified signals from a read operation) from selected memory cell pillars in block BLK0 to data lines 270₀ through 270_{N}. Memory device 200 can include additional circuitry (not shown in FIG. 2) like sense and buffer circuitry 120 of FIG. 1. In a read operation associated with block BLK0, the additional circuitry can operate to determine the values of information read from the selected memory cell strings of block BLK0 based on the signals provided to data lines 270₀ through 270_{N} by sensing circuits 277₀ through 277_{N} in block BLK0. In a write operation associated with block BLK0, sensing circuits 277₀ through 277_{N} in block BLK0 can operate to pass information (to be stored in memory cell pillars of selected memory string) from additional circuitry (e.g., like sense and buffer circuitry 120 of FIG. 1) to the selected memory cell pillars.

Sensing circuits 277₀ through 277_{N} in block BLK1 can operate in a read operation or write operation in a similar fashion as sensing circuits 277₀ through 277_{N} in block BLK1.

FIG. 3A shows a detailed schematic diagram including blocks BLK0 and BLK1 and associated sensing circuits of blocks BLK0 and BLK1 of memory device 200 of FIG. 2, according to some embodiments described herein. For simplicity, only some of the sensing circuits (e.g., sensing circuits 277₀, 277₁, and 277₂) in FIG. 2 are shown in FIG. 3A. FIG. 3B show details (e.g., transistors and associated connections) of one of the sensing circuits and some of the memory cell strings of FIG. 3A.

As shown in FIG. 3A, memory device 200 can include conductive lines 247₀, 247₁, and 247₂ coupled to respective sensing circuits 277₀, 277₁, and 277₂). Memory device 200 can include conductive connections 265 coupled between respective select gates 260 and respective conductive lines 247₀, 247₁, and 247₂. In the physical structure of memory device 200, each conductive connection 265 can be part of a contact structure (e.g., contact structure 560 in FIG. 5) associated with a memory cell pillar (e.g., pillar 550 in FIG. 5) of memory device 200.

FIG. 3A shows an example where each of sensing circuit 277₀, 277₁, and 277₂ is coupled to particular memory cell strings (and associated memory cell pillars) of respective subblocks. However, the memory cell strings coupled to each of sensing circuit 277₀, 277₁, and 277₂ can be different from the memory cell strings shown in FIG. 3A. For example, sensing circuit 277₀ can be coupled to memory cell string 234a of subblock SBj (as shown in FIG. 3A) and memory cell string 232a (instead of memory cell string 231a) of subblock SB0.

In FIG. 3A, directions X, Y, and Z can be relative to the physical directions (e.g., three dimensional (3D) dimensions) of the structure of memory device 200. For example, the Z-direction can be a direction perpendicular to (e.g., vertical direction with respect to) a substrate of memory device 200 (e.g., a substrate 599 shown in FIG. 5). The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3A. As shown in FIG. 3A, each select line can carry an associated separate select signal. For example, in sub-block SB0 of block BLK0, select line (e.g., drain select line) 280₀ can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 280₀ can carry signal (e.g., drain select-gate signal) SGD1₀. In sub-block SBj of block BLK1, select line (e.g., drain select line) 280ⱼ can carry signal (e.g., drain select-gate signal) SGD1ⱼ. Sub-blocks SB0 and SBj of block BLK1 can share select line 284 that can carry signal (e.g., source select-gate signal) SGS1.

As shown in FIG. 3A, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z directions (e.g., dimensions), with respect to the structure (shown in FIG. 4) of memory device 200.

In FIG. 3A, each of the memory cell strings (e.g., memory cell string 231a) of memory device 200 can include series-connected memory cells that include one of memory cells 210, one of memory cells 211, one of memory cells 212, and one of memory cells 213. FIG. 3A shows an example of four memory cells 210, 211, 212, and 213 in each memory cell string. The number of memory cells in each memory cell string can vary. For example, each memory string can include up to hundreds (or more) of memory cells.

As shown in FIG. 3A, each drain select circuit (e.g., select circuit 241a) can include one of select gates 260. Each source select circuit (e.g., select circuit 241′a) can include one of select gates 264.

Each select gate 260 in FIG. 3A can operate like a transistor. For example, select gate 260 of select circuit 241a can operate like a field effect transistor (FET), such as a metal-oxide semiconductor FET (MOSFET). An example of such a MOSFET include an n-channel MOS (NMOS) transistor.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer (e.g., a piece) or a region of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor (e.g., FET)) between the portion of the conductive material and the portion of the channel material.

In this description, a material can include a single material (e.g., a single layer of material) or a combination of multiple materials (e.g., multiple layers of material). For example, a conductive material can include a single conductive material (e.g., a single layer of conductive material) or a combination of multiple conductive materials (e.g., multiple layers of different conductive materials). In another example, a dielectric material can include a single dielectric material (e.g., a single layer of dielectric material) or a combination of multiple dielectric materials (e.g., multiple layers of different dielectric materials).

FIG. 3A shows an example where memory device 200 includes one drain select gate (e.g., select gate 260) in each drain select circuit, and one source select gate (e.g., select gate 264) in each source select circuit coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 3B shows a sensing circuit 277, which corresponds to one of sensing circuit 277₀, 277₁, and 277₂ of FIG. 3A (or sensing circuit 277₀ through 277_{N} of FIG. 2). Data line 270 in FIG. 3B corresponds to one of data lines 270₀ through 270_{N} of FIG. 3A. Control gates 220, 221, 222, and 223 (associated with signal WL0, WL1, WL2, and WL3) of FIG. 3B correspond to control gates 220₀, 221₀, 222₀, and 223₀, respectively, associated with signals WL0₀, WL1₀, WL2₀, and WL3₀ (or control gates 220₁, 221₁, 222₁, and 223₁, respectively, associated with WL0₁, WL1₁, WL2₁, and WL3₁) of FIG. 3A. In FIG. 3B, select gates 264 and 260 correspond to select gates 264 and 260, respectively, of FIG. 3A. In FIG. 3B, signal SGS on select line 284 correspond to signal SGS0 on select line 284 of FIG. 3A. Source 290 and signal SRC correspond to source 290 and signal SRC of FIG. 3A. Signals SGD₀, SGD₁, SGD₂, and SGD₃ correspond to signals SGD0₀ through SGD0ⱼ (or signals SGD1₀ through SGD1ⱼ) of FIG. 3A. FIG. 3B shows an example of four subblocks SB0, SB1, SB2, and SB3 of a block (e.g., block BLK0 or BLK1 of FIG. 3A).

In FIG. 3B, conductive line 247 corresponds to one of conductive lines 247₀, 247₁, and 247₂ of FIG. 3A. Conductive line 247 can be called a local sense line (or alternatively called a sense node). As shown in FIG. 3B, conductive line 247 can be coupled to multiple memory cell strings in which each memory string can include respective memory cells 210, 211, 212, and 213 and an associated memory cell pillar. In FIG. 3B, conductive connections 265 are part of memory cell pillars (e.g., four memory cells pillars) associated with respective memory cell strings (e.g., four memory cell strings).

As shown in FIG. 3B, sensing circuit 277 can include transistors T1, T2, T3, and T4 coupled to conductive line 247 and data line 270 in ways shown in FIG. 3B. Transistors T1, T2, T3, and T4 can have the same transistor type. In an example, transistors T1, T2, T3, and T4 are n-type transistors (e.g., n-channel metal-oxide semiconductor (NMOS) transistors). Transistors T1, T2, T3, and T4 can be configured (e.g., structured) to in the same operating mode. In an example, transistors T1, T2, T3, and T4 can be configured (e.g., structured) as enhancement-mode transistors.

Each of transistors T1, T2, T3, and T4 can include terminals (e.g., source S (e.g., source) and D (e.g., drain), a channel (transistor channel Ch), and a gate (e.g., of gates G1, G2, G3, and G4). In this description, source and drain (non-gate terminals) of a transistor are used interchangeably. As shown in FIG. 3, gates G2 and G4 can be coupled to each other. Thus, transistors T2 and T4 can share a gate.

As shown in FIG. 3B, terminals S of transistors T2 and T3 can be coupled to each other through a conductive connection 248. Terminals D of transistors T3 and T4 can be coupled to each other through a conductive connection 249.

Memory device 200 can include conductive lines 292, 293, and 294 coupled to gate G1 of transistor T1, gate G2 of transistor G2, and terminal S of transistor T4, respectively. Conductive line 292 can be associated with (e.g., can receive) a signal WE (e.g., a write enable signal). Conductive line 293 can be associated with (e.g., can receive) a signal RE (e.g., a read enable signal). Conductive line 294 can be associated with (e.g., can receive) a signal SL (e.g., local source line signal).

As shown in FIG. 3B, gate G3 of transistor T3 and terminal S of transistor T1 can be coupled to conductive line 247, which is coupled to four memory cell pillars. Thus, in the example of FIG. 3B, sensing circuit 277 can be coupled to four memory cell pillars. However, sensing circuit 277 can be coupled to a multiple of memory cell pillars that is different from four.

As shown in FIG. 3B, sensing circuit 277 can include a circuit path 277R and a circuit path 277W. Circuit path 277R can be part of a read circuit path between data line 270 and circuitry (e.g., like sense and buffer circuitry 120 of FIG. 1) of memory device 200. Circuit path 277W can be part of a write circuit path between data line 270 and circuitry (e.g., like sense and buffer circuitry 120 of FIG. 1) of memory device 200. Circuit paths 277R and 277W can be activated one at a time.

In operation, sensing circuit 277 can operate as a capacitive sensing circuit. Conductive line 247 (coupled to gate G3 of transistor T3) can be part of sense node (e.g., sense line). Transistor T3 can operate as a sense transistor during a read operation as part of determining the value of information read from selected memory cell strings of memory device 200. For example, transistor T3 can operate to provide a capacitive structure, which can be formed by gate G3 and a portion of semiconductor structure that form part of the source, drain, and channel of transistor T3. The capacitive structure (from transistor T3) allows reading (e.g., sensing) the potential at the sense node (e.g., conductive line 272) that coupled the pillar of a selected memory cell string being read in a read operation. The sensed potential value can be provided to data line 270. Other circuitry (e.g., like sense and buffer circuitry 120 of FIG. 1) on the read circuit path of memory device 200 can operate to determine the value of information read from selected memory cell string based on the sensed potential.

Circuit path 277R can be activated during a read operation of a memory device (while circuit path 277W is deactivated). In a read operation, signal RE can have a value (e.g., a relatively high voltage value) to turn on transistors T2 and T4 (e.g., to activate circuit path 277R). In a read operation, signal WE can have a value (e.g., a relatively low voltage value) to turn off transistor T1 (e.g., to deactivate circuit path 277W).

Circuit path 277W can be activated during a write operation of memory device (while circuit path 277E is deactivated). In a write operation, signal WE can have a value (e.g., a relatively high voltage value) to turn on transistor T1 (e.g., to activate circuit path 277W). In a write operation, signal RE can have a value (e.g., a relatively low voltage value) to turn off transistor T2 and T4 (e.g., to deactivate circuit path 277R).

FIG. 4 shows a top view of a structure of a portion of the memory device of FIG. 3 including a region of a memory array 201 including blocks BLK0 and BLK1, data lines extending over blocks BLK0 and BLK1, structures 451 between blocks, and a footprint (e.g., a collective footprint) 277A of sensing circuits 277₀ through 277_{N} in respective blocks BLK0 and BLK1, according to some embodiments described herein.

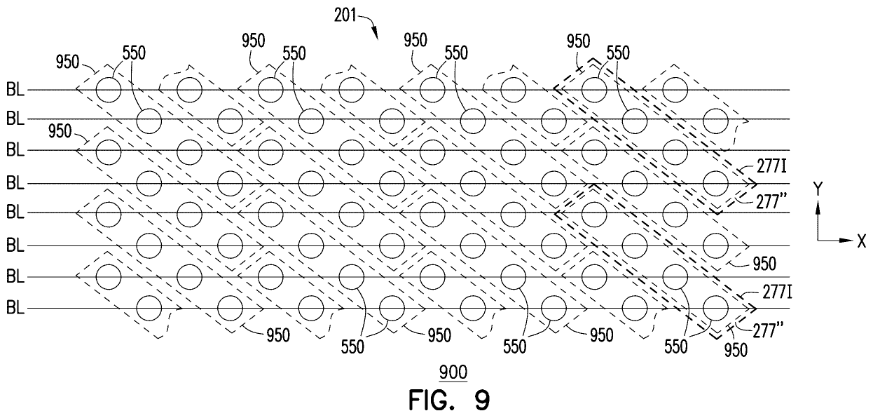

As shown in FIG. 4, sensing circuits 277₀ through 277_{N} can be located in memory array 201 under data lines 270₀ through 270_{N}. Each of sensing circuits 277₀ through 277_{N} (e.g., sensing circuit 277 in FIG. 3B) has a respective footprint that can correspond to an area (e.g., layout) of each sensing circuit 277 (e.g., sensing circuit 277 in FIG. 3B). In an example, FIG. 9 (described below) shows an example footprint (e.g., footprint 277I) of an individual sensing circuit (e.g., sensing circuit 277 in FIG. 3B) of the memory device (e.g., memory device 900) described herein. In FIG. 4, footprint 277A can correspond to a collective area (e.g., a collective layout) from the top view of sensing circuits 277₀ through 277_{N}.

In FIG. 4, structures 451 can be formed to separate (physically separate) one block and another block of memory device 200. Two adjacent blocks (e.g., blocks BLK0 and BLK1) can be separated from each other by one of structures 451. Each structure 451 can have a length in the Y-direction. Each structure 451 can include a dielectric material (e.g., silicon dioxide) or a combination of a dielectric material and additional material (e.g., a non-conductive material). Each structure 451 can include a slit (not labeled) and materials (not labeled) formed in (e.g., filled in) the slit. The slit can include (or can be part of) a trench between adjacent blocks (e.g., blocks BLK0 and BLK1). Structures 451 can be called a dielectric structure or a slit structure. The regions of memory device 200 at which structures 451 are located can be called slit regions.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. Signals SGD0₀, SGD1₀, SGD2₀, and SGD3₀ can correspond to some of signals SGD0₀ through SGD0ⱼ in FIG. 3A. In FIG. 4, the select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction from memory array 201 to region 454. FIG. 4 shows an example where each block of memory device 200 can have four sub-blocks SB0, SB1, SB2, and SB3. However, the number of sub-blocks can be different from four.

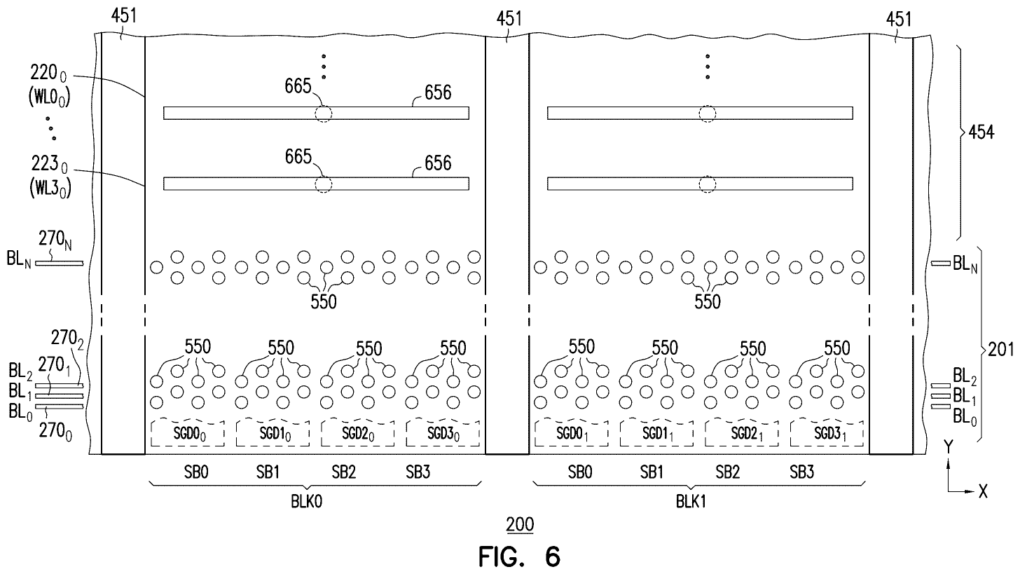

Block BLK1 can have a structure like block BLK0. As shown in FIG. 4, block BLK1 can include sub-blocks SB0, SB1, SB2, and SB3 and select lines (e.g., drain select lines) associated with signals SGD0₁, SGD1₁, SGD2₁, and SGD3₁ (which can correspond to some of signals SGD1₀ through SGD1ⱼ in FIG. 3A). As described below with reference to FIG. 6, region 454 can be a location where conductive contacts associated with control gates (e.g., control gates 220₀, 221₀, 222₀, and 223₀ and control gates 220₁, 221₁, 222₁, and 223₁ in FIG. 3A) of memory device 200 can be formed.

A side view (e.g., cross-section) at memory array (memory cell array) 201 of memory device 200 along line 5A-5A in FIG. 4 is shown in FIG. 5.

FIG. 5 shows a side view (e.g., cross-section) of a structure of a portion of memory device 200 of FIG. 4 including tiers (tiers of materials) 525 that include respective memory cells (e.g., tiers of memory cells) and control gates (e.g., tiers of control gates) associated with (e.g., to control) the memory cells, according to some embodiments described herein. FIG. 5 also partially shows other blocks (on the left and right sides of blocks BLK0 and BLK1) of memory device 200. FIG. 5 shows an example of four tiers of memory cells associated with four control gates (associated with signals WL0, WL1, WL2, and WL3). However, memory device 200 can include up to hundreds of tiers of memory cells (or more than hundreds of tiers of memory cells). The number of tiers of memory cells can be the same as the number of the control gates (tiers of control gates).

For simplicity, some elements of memory device 200 (and other memory devices described herein) may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Moreover, the dimensions (e.g., physical structures) of the elements of memory device 200 (and other memory devices) in the drawings described herein are not scaled. The description of the same elements of memory device 200 described above with reference to FIG. 2, FIG. 3A, and FIG. 3B are also not repeated.

As shown in FIG. 5, memory device 200 can include a substrate 599, source 290 formed over substrate 599, and different levels 501 through 512 over substrate 599 in the Z-direction. Levels 501 through 512 are physical device levels of memory device 200 over substrate 599. Memory device 200 can include a dielectric material 581 formed over at least a portion of memory device 200. Memory cells 210, 211, 212, and 213 of the memory cell strings (e.g., memory cell string 231a in FIG. 3A) of respective sub-blocks SB0, SB1, SB2, and SB3 of each of blocks BLK0 and BLK1 can be formed over substrate 599 and source 290 (e.g., formed vertically in Z-direction in respective levels among levels 501 through 512).

As shown in FIG. 5, data line 270₁ (associated with signal BL₁) can extend in the X-direction across the blocks (e.g., blocks BLK0 and BLK1 and other blocks) of memory device 200. Data line 270₁ can be shared by respective memory cell strings (including memory cell string 231a) of the blocks.

In FIG. 5, the select lines (e.g., four drain select lines in the X-direction) indicated by signal SGD can correspond to respective select lines (e.g., drain select lines) of a respective block of blocks BLK0 and BLK1. For example, in sub-blocks SB0, SB1, SB2, and SB3 of block BLK0, the select lines (e.g., four drain select lines) indicated by signal SGD can correspond to respective select lines associated with signals SGD0₀, SGD1₀, SGD2₀, and SGD3₀ of block BLK0 shown in FIG. 4. In another example, in sub-blocks SB0, SB1, SB2, and SB3 of block BLK1, the select lines (e.g., four drain select lines in the X-direction) indicated by signal SGD can correspond to respective select lines associated with signals SGD0₁, SGD11, SGD2₁, and SGD3₁ of block BLK1 shown in FIG. 4.

As shown in FIG. 5, the select lines (e.g., four drain select lines) in the same block (e.g., block BLK0) can include respective conductive regions (e.g., four conductive regions) that are electrically separated from each other and can be located on the same level (e.g., level 512) in the Z-direction of memory device 200 and located over the control gates (in the Z-direction) of the respective block.

The select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 3A. In another example, in block BLK1, the select line indicated by signal SGS can correspond to the select line (e.g., source select line) associated with signals SGS1 of block BLK1 shown in FIG. 3A.

In FIG. 5, for simplicity, control gates (e.g., four control gates) of blocks BLK0 and BLK1 are indicated by the same signals WL0, WL1, WL2, and WL3. For example, in block BLK0, the control gates indicated by signals WL0, WL1, WL2, and WL3 can correspond to respective control gates associated with signals WL0₀, WL1₀, WL2₀, and WL3₀, respectively, of block BLK0 shown in FIG. 3A. In another example, in block BLK1 in FIG. 5, the control gates indicated by signals WL0, WL1, WL2, and WL3 can correspond to respective control gates associated with signals WL0₁, WL1₁, WL2₁, and WL3₁, respectively, of block BLK1 shown in FIG. 3A.

As shown in FIG. 5, memory device 200 can include dielectric materials (e.g., silicon dioxide) 521 located on levels 503, 505, 507, 509, and 511. Dielectric materials 521 in a respective block are interleaved with conductive materials 522. Conductive materials 522 can form respective control gates (associated with signals WL0, WL1, WL2, and WL3) in the respective block. As shown in FIG. 5, dielectric materials 521 can be located on respective levels among levels 501 through 512. Conductive materials 522 can be located on respective levels (e.g., levels 502, 504, 506, 508, 510, and 512) among levels 501 through 512 that are interleaved with the levels of dielectric materials 521. Examples of conductive materials 522 (which form the control gates) include a single conductive material (e.g., single metal, e.g., tungsten) or a combination of different layers of conductive materials. For example, each of the control gates of blocks BLK0 and BLK1 can include (e.g., have multi-layers of) aluminum oxide, titanium nitride, tungsten.

As shown in FIG. 5, dielectric materials 521 can form levels of dielectric materials 521. Conductive materials 522 can form levels of conductive materials 522 that are interleaved with the levels of dielectric materials 521. The levels of dielectric materials 521 and the levels of conductive materials 522 can form tiers 525 of memory device 200. Each tier 525 can include a level of dielectric material 521 and a level of conductive material 522. For simplicity, only some of tiers 525 are labeled in FIG. 5. As shown in FIG. 5, tiers 525 can be located one over another and can include respective levels of memory cells 210, 211, 212, and 213, and control gates associated with the memory cells. FIG. 5 shows a few tiers (e.g., only two tiers 525 are labeled) of memory device 200 as an example. However, memory device 200 can include up to hundreds of tiers (or more than hundreds of tiers).

As shown in FIG. 5, memory device 200 can include pillars (memory cell pillars) 550 in blocks BLK0 and BLK1. Each of pillars 550 can be part of a respective memory cell string (e.g., memory cell string 231a). Each of the pillars 550 can have length extending through at least a portion of the levels of dielectric materials 521 and the levels of conductive materials 522 (associated with tiers of memory cells) in the Z-direction (e.g., extending vertically from substrate 599) between substrate 599 and data line 270₁. As shown in FIG. 5, the Z-direction is also a direction at which the length of pillar 550 extends from one tier to another tier, which is also a direction from levels of dielectric materials 521 to levels of conductive materials 522.

As shown in FIG. 5, memory cells 210, 211, 212, and 213 of respective memory cell strings (e.g., memory cell string 231a) can be located in different levels (e.g., levels 504, 506, 508, and 510) in the Z-direction of memory device 200. The control gates (associated with signals WL0, WL1, WL2, and WL3) of each of blocks BLK0 and BLK1 can be located on the same levels (e.g., levels 504, 506, 508, and 510) at which memory cells 210, 211, 212, and 213 are located. Thus, memory cells 210, 211, 212, and 213 and the control gates of blocks BLK0 and BLK1 can be located (e.g., vertically located) along respective portions (e.g., portions on levels 504, 506, 508, and 510) of pillars 550 in the Z-direction.

Substrate 599 of memory device 200 can include monocrystalline (also referred to as single-crystal) semiconductor material. For example, substrate 599 can include monocrystalline silicon (also referred to as single-crystal silicon). The monocrystalline semiconductor material of substrate 599 can include impurities, such that substrate 599 can have a specific conductivity type (e.g., n-type or p-type).

As shown in FIG. 5, memory device 200 can include circuitry 595 located in (e.g., formed in) substrate 599. At least a portion of the circuitry 595 can be located in a portion of substrate 599 that is under (e.g., directly under) memory cell strings of blocks BLK0 and BLK1. Circuitry 595 can include transistors (e.g., Tr1 and Tr2) that can be part of decoder circuits, driver circuits (e.g., word line drivers), buffers, sense amplifiers (which are different from sensing circuits 277₀ through 277_{N}), charge pumps, and other circuitry of memory device 200.

In FIG. 5, source 290 can include a conductive material (or materials, e.g., different levels of different materials) and can have a length extending in the X-direction. FIG. 5 shows an example where source 290 can be formed over a portion of substrate 599 (e.g., by depositing a conductive material over substrate 599). Alternatively, source 290 can be formed in or formed on a portion of substrate 599 (e.g., by doping a portion of substrate 599).

The select lines (associated with signals SGS and SGD) of blocks BLK0 and BLK1 can have the same material (or materials) as the control gates (associated with signals WL0, WL1, WL2, and WL3) of blocks BLK0 and BLK1. Alternatively, the select gates associated with signal SGS, SGD, or both have material (or materials) different from the material of the control gates.

As shown in FIG. 5, memory device 200 can include contact structures 560. Each contact structure 560 can be considered as part of a respective pillar 550. Each pillar 550 can be coupled to a respective sensing circuit 277 by a respective contact structure 560. Each contact structure 560 can include a conductive material (or conductive materials) to allow conduction of electrical signal (e.g., current) between pillar 550 and a respective data line through a respective sensing circuit 277.

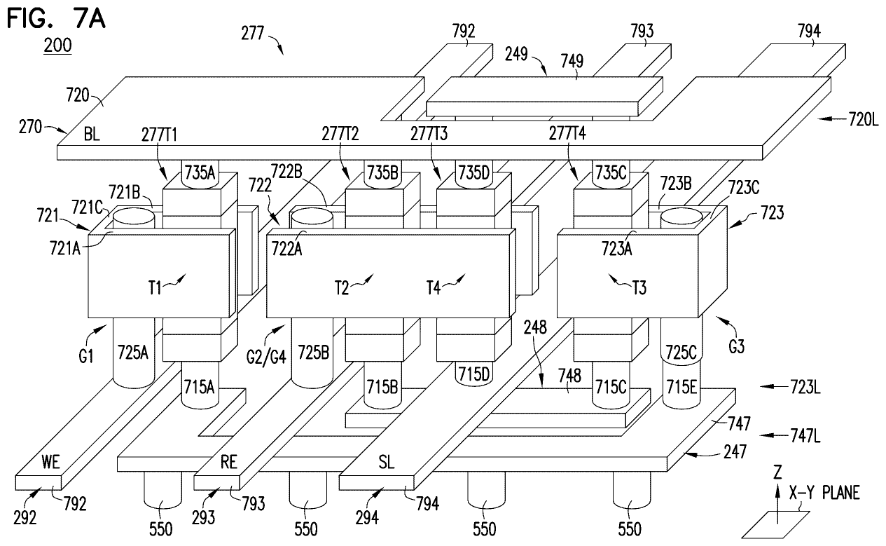

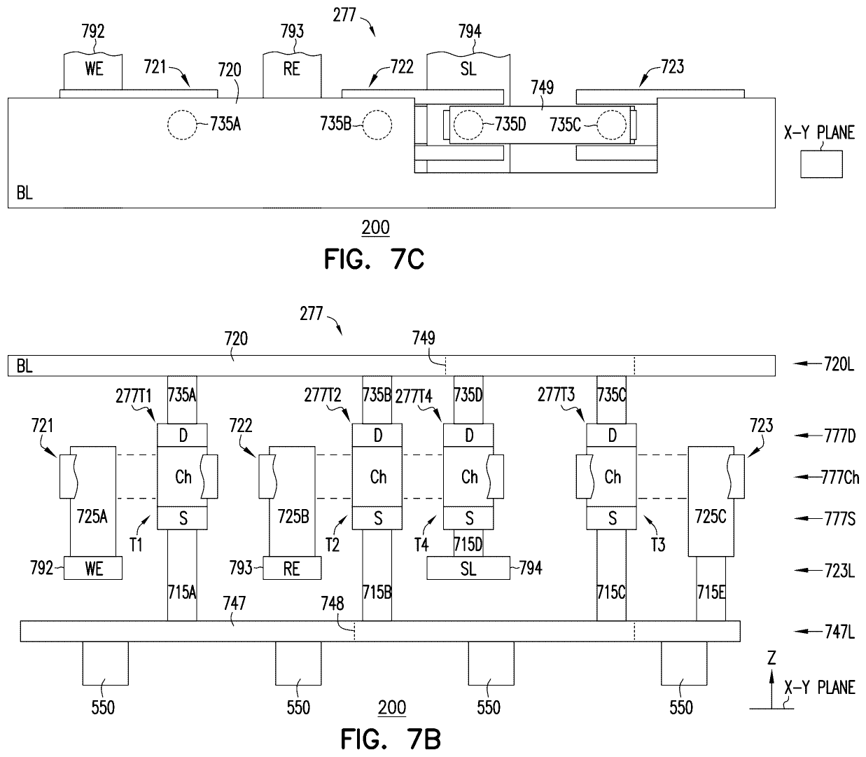

Sensing circuit 277 corresponds to sensing circuit 277 of FIG. 3B and one of sensing circuits 277₀ through 277_{N} of FIG. 2. For simplicity, FIG. 5 omit detailed structure of sensing circuit 277. FIG. 7A shows detailed structure of circuit 277 of FIG. 5.

FIG. 6 shows top views of a structure of a portion of memory device 200 of FIG. 4 and FIG. 5, according to some embodiments described herein. As shown in FIG. 6, pillars 550 (shown in top view) can be located in the region included in memory array 201, which is adjacent region 454. Region 454 can be called conductive contact region (e.g., word line conductive contact region) of memory device 200. As shown in FIG. 6, in region 454, memory device 200 can include conductive contacts (e.g., word line contacts) 665. Conductive contacts 665 can include metal (e.g., tungsten or other conductive materials). Conductive contacts 665 can contact (form electrical connection with) respective control gates (e.g., control gates 220₀ through 223₀ located under conductive contacts 665, hidden from the top view of FIG. 6). Conductive contacts 665 can be part of respective access lines (e.g., word lines) of memory device 200. Conductive contacts 665 allow signals (e.g., signals WL0₀ through WL3₀ in block BLK0) to be provided to respective control gates of block BLK0 through conductive contacts 665 in FIG. 6.

In the top view of FIG. 6, control gates 220₀ through 223₀ are located one over another (stacked in tiers 525 shown in FIG. 5). As shown in FIG. 6, memory device 200 can include conductive lines 656 coupled to respective conductive contacts 665. In block BLK0, signals WL0₀ through WL3₀ can be provided to respective control gates 220₀ through 223₀ through respective conductive lines 656 in block BLK0. For simplicity, FIG. 6 shows only two of conductive contacts 665 and two respective conductive lines 656 in each of blocks BLK0 and BLK1. The two conductive contacts 665 in a respective block (e.g., block BLK0) can be associated (coupled to) with two of the control gates (e.g., two of control gates 220₀ through 223₀) of the respective block (e.g., block BLK0) of memory device 200. For example, two conductive contacts 665 in block BLK0 in FIG. 6 can be associated with control gate 223₀ and control gate 222₀ in block BLK0.

Similarly, for block BLK1 in FIG. 6, conductive contacts and conductive lines (e.g., not labeled) can be formed at region 454 to allow signals (e.g., signals WL0₁, WL1₁, WL2₁, and WL31 in block BLK1 shown in FIG. 3A) to be provided to respective control gates of block BLK1 through the conductive contacts at region 454.

FIG. 7A shows a perspective view (e.g., 3-D view) of a structure of a portion of memory device 200 of FIG. 2 through FIG. 6 including a structure of sensing circuit 277, according to some embodiments described herein. FIG. 7B shows a side view (e.g., cross-section with respect to a side view) of FIG. 7A. FIG. 7C shows a top view (e.g., cross-section with respect to a top view) of FIG. 7A.

The elements associated with the structure of the portion of memory device 200 shown in FIG. 7A, FIG. 7B, and FIG. 7C correspond to some of the elements that are schematically shown in FIG. 3B (and other figures described herein). In FIG. 7A, FIG. B, and FIG. 7C, the X-Y plane symbol represents a plane view (X-Y plane view) associated with the structure of memory device 200. The X-direction and the Y-direction (not labeled) are parallel to the plane view represented by the X-Y plane symbol. The Z-direction symbol (FIG. 7A and FIG. 7C) represents a Z-direction (e.g., vertical direction) perpendicular to the X-Y plane view relative to the structure of memory device 200.

The following description refers to FIG. 7A, FIG. 7B, and FIG. 7C. In the description associated with FIG. 7A, FIG. 7B, and FIG. 7C (and other figures), the conductive material of an element (e.g., a conductive region or a conductive contact) can include metal, conductively-doped polysilicon, or other conductive materials.

As shown in FIG. 7A and FIG. 7B, data line 270 can include a conductive region 720, which is part of a conductive material included in data line 270. Conductive region 720 can include a level of conductive material (e.g., a layer of conductive material) located on a level 720L (with respect to the Z-direction) of memory device 200.

As shown in FIG. 7A and FIG. 7B, conductive connection 249 can include a conductive region 749, which is part of a conductive material included in conductive connection 249. Conductive region 749 can include a level of conductive material (e.g., a layer of conductive material) located on a level 720L (with respect to the Z-direction) of memory device 200. Conductive region 749 can be located on the same level (e.g., level 720L) as conductive region 747.

As shown in FIG. 7A and FIG. 7B, conductive line 247 can include a conductive region 747, which is part of a conductive material included in conductive line 247. Conductive region 747 can include a level of conductive material (e.g., a layer of conductive material) located on a level 747L (with respect to the Z-direction) of memory device 200.

As shown in FIG. 7A and FIG. 7B, pillars (memory cell pillars) 550 can be coupled to each other through conductive region 747 of conductive line 247.

As shown in FIG. 7A and FIG. 7B, conductive connection 248 can include a conductive region 748, which is part of a conductive material included in conductive connection 248. Conductive region 748 can include a level of conductive material (e.g., a layer of conductive material) located on a level 747L (with respect to the Z-direction) of memory device 200. Conductive region 748 can be located on the same level (e.g., level 747L) as conductive region 747.

As shown in FIG. 7A and FIG. 7B, conductive lines 292, 293, and 294 can include respective conductive regions 792, 793, and 794 separated from each other. Conductive regions 792, 793, and 794 can include separate conductive materials (e.g., separate stripes (layers) of conductive materials).

As shown in FIG. 7A and FIG. 7B, conductive regions 792, 793, and 794 can be located on a same level (e.g., level 723L) of memory device 200. As shown in FIG. 7A and FIG. 7B, level 723L is between levels 720L and 747L (with respect to the Z-direction).

As shown in FIG. 7A and FIG. 7B, part of transistors T1, T2, T3, and T4 can include (e.g., can be formed from) semiconductor structures 277T1, 277T2, 277T3, and 277T4, respectively.

Each of semiconductor structures 277T1, 277T2, 277T3, and 277T4 can include a thin-film structure (e.g., thin-film transistor or TFT) having respective portions (semiconductor portions) that form terminal D (e.g., the drain), terminal S (e.g., the source), and a channel (transistor channel) Ch of a respective transistor (among transistors T1, T2, T3, and T4).

For example, as shown in FIG. 7A and FIG. 7B, semiconductor structure 277T1 can include a portion forming terminal D, a portion forming terminal S, and a portion (middle portion between the portions forming terminals D and S) forming channel Ch. The portions of semiconductor structure 277T1 that form respective terminal S, channels Ch, and drain of transistor T1 can be stacked one over another (e.g., stacked vertically in the Z-direction). Thus, transistor T1 can include source, channel, and drain that are vertically formed (in the Z-direction).

Portions of semiconductor structure 277T1 that form terminals D and S and channel Ch can have different doping concentrations. For example, each of the portions of semiconductor structure 277T1 that forms terminal D or S can have a higher concentration than the portion of semiconductor structure 277T1 that forms channel Ch. In an example, transistor T1 includes an n-type transistor (e.g., NMOS transistor), such that the portions of semiconductor structure 277T1 that form terminals D and S include n-type semiconductor material (e.g., n-type conductivity).

Similarly, as shown in FIG. 7B, respective portions that form terminal S, channel Ch, and terminal D of each of semiconductor structures 277T2, 277T3, and 277T3 can be stacked one over another (e.g., stacked vertically in the Z-direction). Like semiconductor structure 277T1, each of semiconductor structures 277T2, 277T3, and 277T3 can include n-type semiconductor material in the portions that form terminals D and S of respective transistors T2, T3, and T4. The portions of semiconductor structures 277T2, 277T3, and 277T4 that form terminals D and S of respective transistors T2, T3, and T4 can have a higher concentration than the portion of semiconductor structures 277T2, 277T3, and 277T3 that form channels Ch.

As shown in FIG. 7B portions of semiconductor structures 277T1, 277T2, 277T3, and 277T4 that form respective terminals D of transistors T1, T2, T3, and T4 can be located on the same level 777D of memory device 200. Portions of semiconductor structures 277T1, 277T2, 277T3, and 277T4 that form respective terminals S of transistors T1, T2, T3, and T4 can be located on the same level 777S of memory device 200. Portions of semiconductor structures 277T1, 277T2, 277T3, and 277T4 that form respective channels Ch of transistors T1, T2, T3, and T4 can be located on the same level 777Ch of memory device 200. As shown in FIG. 7A and FIG. 7B, levels 777D, 777S, and 777Ch are between levels between levels 720L and 747L.

Thus, semiconductor structures 277T1, 277T2, 277T3, and 277T4 can include respective portions (e.g., portions forming terminals D, terminals D, or channels Ch) that are located on the same level (e.g., level 777D, 777S, or 777Ch) of memory device 200.

As shown in FIG. 7A and FIG. 7B, memory device 200 can include conductive contacts 715A, 715B, 715C, 715D, and 715E, which can include (can be formed from) respective conductive pillars having a conductive material. Memory device 200 can include conductive contacts 735A, 735B, 735C, and 735D, which can include (can be formed from) respective conductive pillars having a conductive material.

Conductive contacts 715A, 715B, 715C, and 715D can be coupled to (e.g., can contact) respective portions of semiconductor structures 277T1, 277T2, 277T3, and 277T4 that form respective terminals S of transistors T1, T2, T3, and T4. Conductive contact 715E can be coupled to (e.g., can contact) conductive region 747. Conductive contacts 735A, 735B, 735C, and 735D can be coupled to (e.g., can contact) respective portions of semiconductor structures 277T1, 277T2, 277T3, and 277T4 that form respect terminals D of transistors T1, T2, T3, and T4.

As shown in FIG. 7A and FIG. 7B, conductive contact 715A can be located between and contacting (directly coupled to) conductive region 747 and the portion of the semiconductor structure 277T1 that forms terminal S of transistor Ti. Conductive contact 735A can be located between and contacting (directly coupled to) conductive region 720 and the portion of the semiconductor structure 277T1 that forms terminal D of transistor T1.

Conductive contact 715B can be located between and contacting (directly coupled to) conductive region 748 and the portion of the semiconductor structure 277T2 that forms terminal S of transistor T1. Conductive contact 735B can be located between and contacting (directly coupled to) conductive region 720 and the portion of the semiconductor structure 277T2 that forms terminal D of transistor T2.

Conductive contact 715C can be located between and contacting (directly coupled to) conductive region 748 and the portion of the semiconductor structure 277T3 that forms terminal S of transistor T3. Conductive contact 735C can be located between and contacting (directly coupled to) conductive region 720 and the portion of the semiconductor structure 277T3 that forms terminal D of transistor T3.

Conductive contact 715D can be located between and contacting (directly coupled to) conductive region 794 and the portion of the semiconductor structure 277T4 that forms terminal S of transistor T4. Conductive contact 735D can be located between and contacting (directly coupled to) conductive region 749 and the portion of the semiconductor structure 277T4 that forms terminal D of transistor T4.

As shown in FIG. 7A, FIG. 7B, and FIG. 7C, memory device 200 can include conductive gate structures 721, 722, and 723. For simplicity, FIG. 7A, 7B, and FIG. 7C do not show a dielectric material (e.g., gate oxide) between conductive gate structures 721, 722, and 723 and respective semiconductor structure 277T1, 277T2, 277T3, and 277T4. For simplicity, FIG. 7B show partial view of conductive gate structures 721, 722, and 723. Gates G1, G2, and G3 can be part of conductive gate structures 721, 722, and 723, respectively.

Conductive gate structure 721 can have a U-shape as shown in FIG. 7A and FIG. 7C. Conductive gate structure 721 can include a conductive region 721A, a conductive region 721B, and a conductive region 721C. Conductive region 721A can be adjacent and separated from a side (e.g., a front side) of semiconductor structure 277T1. Conductive region 721B can be adjacent and separated from another side (e.g., a back side opposite from the front side) of semiconductor structure 277T1. Conductive region 721C can be adjacent and separated from a side (e.g., a left side adjacent the front and back sides) of semiconductor structure 277T1. As shown in FIG. 7A, conductive region 721C can be between and joining (connecting) conductive region 721A to conductive region 721B.

Conductive gate structure 722 can include a conductive region 722A and a conductive region 722B. Conductive region 722A can be adjacent and separated from a side (e.g., a front side) of semiconductor structure 277T2 and a side (e.g., a front side) of semiconductor structure 277T3. Conductive region 722B can be adjacent and separated from another side (e.g., a back side opposite from the front side) of semiconductor structure 277T2 and another side (e.g., a back side opposite from the front side) of semiconductor structure 277T3.

Conductive gate structure 723 can have a U-shape as shown in FIG. 7A and FIG. 7C. Conductive gate structure 723 can include a conductive region 723A, a conductive region 723B, and a conductive region 723C. Conductive region 723A can be adjacent and separated from a side (e.g., a front side) of semiconductor structure 277T3. Conductive region 723B can be adjacent and separated from another side (e.g., a back side opposite from the front side) of semiconductor structure 277T3. Conductive region 723C can be adjacent and separated from a side (e.g., a left side adjacent the front and back sides) of semiconductor structure 277T3. As shown in FIG. 7A, conductive region 723C can be between and joining (connecting) conductive region 723A to conductive region 723B.

As shown in FIG. 7A, FIG. 7B, and FIG. 7C, memory device 200 can include conductive contacts 725A, 725B, and 725C, which can include (can be formed from) respective conductive pillars having a conductive material. Conductive contacts 725A, 725B, and 725C can be coupled to (e.g., can contact) respective conductive gate structures 721, 722, and 723 and can be coupled to respective conductive regions 792, 793, and 747 to provide electrical connections between conductive gate structures 721, 722, and 723 and the respective conductive regions.

As shown in FIG. 7A, FIG. 7B, and FIG. 7C, conductive contact 725A can contact (can be directly coupled to) conductive gate structure 721 and conductive region 792 to provide an electrical connection between conductive gate structure 721 and conductive region 792. Conductive contact 725B can contact (can be directly coupled to) conductive gate structure 722 and conductive region 793 to provide an electrical connection between conductive gate structure 723 and conductive region 793. Conductive contact 725C can contact (can be directly coupled to) conductive gate structure 723 and can be coupled to conductive region 747 through conductive contact 715E to provide an electrical connection between conductive gate structure 723 and conductive region 747.

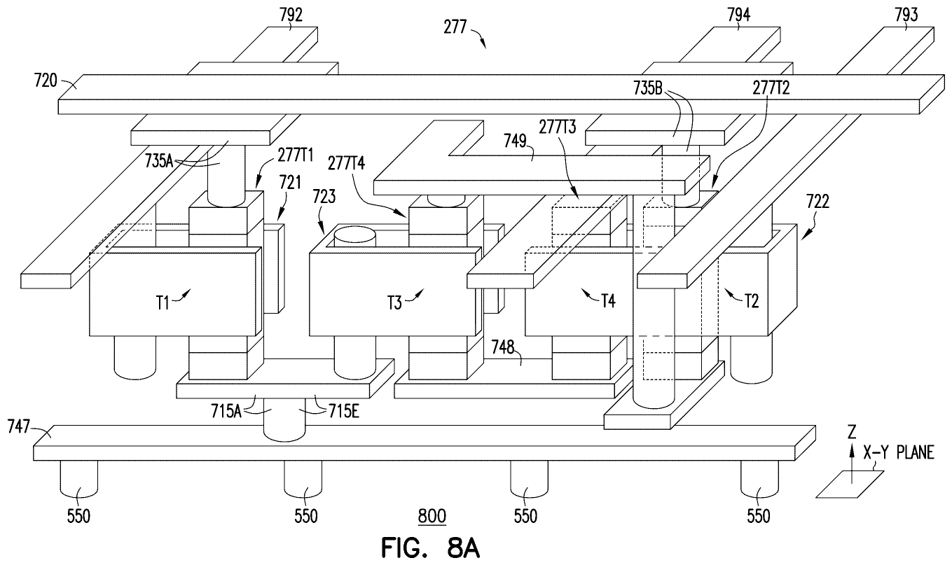

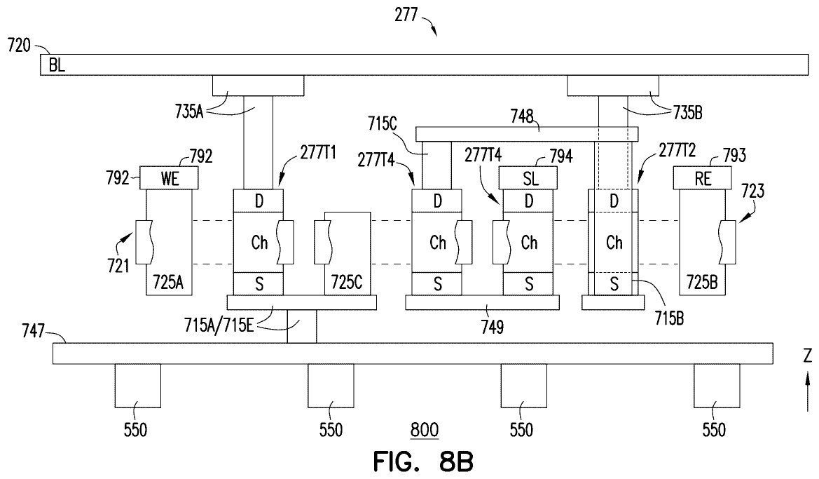

FIG. 8A shows a memory device 800 that can be a variation of memory device 200 including a variation of sensing circuit 277, according to some embodiments described herein. FIG. 8B shows a side view (e.g., cross-section) of memory device 800 of FIG. 8A. Memory device 800 can include elements that are similar to or the same as the elements of memory device 200 described above with reference to FIG. 2 through FIG. 7C. For simplicity, similar or the same elements between memory devices 200 and 800 are given the same labels and their detailed descriptions are not repeated. In FIG. 8A, the Z-direction and the X-Y plane (represented by the Z-direction symbol the X-Y plane symbol, respectively) are similar to those of memory device 200 shown in FIG. 7A and FIG. 7B.

As shown in FIG. 8A and FIG. 8B, memory device 800 can include semiconductor structures 277T1, 277T2, 277T3, and 277T4 associated with transistors T1, T2, T3, and T4, respectively. Each of semiconductor structures 277T1, 277T2, 277T3, and 277T4 can include portions (semiconductor portions) D (e.g., drain), S (e.g., source), and Ch (e.g., channel). Memory device 800 can include conductive gate structures 721, 722, and 723 associated with the gates (e.g., gates G1, G2, G3, and G4, not labeled in FIG. 8A and FIG. 8B) of respective transistors T1, T2, T3, and T4. Memory device 800 can include conductive region 720 associated with signal BL (labeled in FIG. 8B), and conductive region 747 coupled to pillars (memory cell pillars) 550. Memory device 800 can include conductive regions 792, 793, and 794 associated with signals WE, RE, and SL (labeled in FIG. 8B). Memory device 800 can include conductive regions 748 and 749 coupled to respective terminals (e.g., terminal D or S) of respective transistors T2, T3, and T4. Memory device 800 can include conductive contacts 715C, 725A, 725B, and 725C.

Memory device 800 can include conductive contact a conductive contact that can correspond to conductive contact 715A or conductive contact 715E. As shown in FIG. 8A and FIG. 8B, conductive contact 715A can be located between and contacting (directly coupled to) conductive region 747 and the portion of the semiconductor structure 277T1 that forms terminal S of transistor Ti. Conductive contact 715E can be coupled to (e.g., can contact) conductive region 747 and conductive contact 725C.

Memory device 800 can include conductive contact 735A, which can correspond to conductive contact 735A of FIG. 7A and FIG. 7B. As shown in FIG. 8A and FIG. 8B, conductive contact 735A can be located between and contacting (directly coupled to) conductive region 720 and the portion of the semiconductor structure 277T1 that forms terminal D of transistor T1.

Memory device 800 can include conductive contact 735B, which can correspond to conductive contact 735B of FIG. 7A and FIG. 7B. As shown in FIG. 8A and FIG. 8B, conductive contact 735B can be located between and contacting (directly coupled to) conductive region 720 and the portion of the semiconductor structure 277T2 that forms terminal D of transistor T2.

In comparison with memory device 200 of FIG. 7A and FIG. 7B, memory device 800 of FIG. 8A and FIG. 8B include a different number of conductive levels (e.g., layers) between the levels (device levels) of conductive regions 720 and 747. For example, unlike memory device 800, conductive regions 747 and 748 are located (e.g., can be formed) on different levels, and conductive regions 720 and 749 are located (e.g., can be formed) on different levels.

FIG. 9 shows top views of a portion of a memory device 900 including memory array 201, pillars (memory cell pillars) 550 in memory array 201, and data lines associated with signals BL, according to some embodiments described herein. Memory array 201 and pillars 550 can be similar to or the same as memory array 201 and pillars 550, respectively, of memory device 200 (or memory device 800) described above. The data lines associated with signals BL can be similar to or the same as part of data lines 270₀ through 270_{N} of memory device 200 or memory device 800 described above.

For simplicity and not to obscure the example embodiments (e.g., structures of memory device 900) described herein, FIG. 9 omits other elements of memory device 900, such as sensing circuits located over pillars 550 (in the Z-direction) and under data lines associated with signals BL (in the Z-direction) and other elements like the elements of memory device 200 (FIG. 7A) or memory device 800 (FIG. 8A).

As shown in FIG. 9, pillars 550 can be grouped into pillar groups 950. Only some of pillar groups 950 are labeled in FIG. 9 for simplicity. FIG. 9 shows each pillar group 950 including four pillars as an example. However, the number of pillars in each pillar group 950 can be different from four.

Each pillar group 950 can be associated with (e.g., can be coupled to) a sensing circuit like sensing circuit 277 in FIG. 3B, FIG. 5, FIG. 7A, or FIG. 8A. Thus, like memory device 200 of FIG. 7A or memory device 800 of FIG. 8A, pillars 550 (e.g., four pillars in the example of FIG. 9) of each pillar group 950 can be coupled to each other by conductive region of a conductive line. Such a conductive region can be similar to or the same as conductive region 747 of FIG. 7A or FIG. 8A.

In FIG. 9, each pillar group 950 can include pillars 550 from different subblocks of a block of memory device 900. For example, each pillar group 950 can include four pillars 550 from four respective subblocks (e.g., like subblocks SB0, SB1, SB2, and SB4 of block BLK0 in FIG. 6) of a block of memory device 900.

FIG. 9 shows a specific orientation (position) with respect to the X-Y direction from top view of pillars 550 in each pillar group 950 as an example. For example, as shown in FIG. 9, each pillar group 950 has an orientation such that pillars 550 in the same pillar group 950 are lined up (e.g., lined up diagonally) in a direction that is not parallel to the X-direction or the Y-direction. However, the orientation of pillars 550 in each pillar group 950 can be different from the orientation shown in FIG. 9.

FIG. 9 shows specific locations (from top view) of pillars 550 in each pillar group 950 as an example. For example, pillars 550 of each pillar group 950 are located next to each other (e.g., adjacent each other). However, the locations of pillars in each pillar group 950 can be different from those shown in FIG. 9. For example, the locations of some or all or pillars 550 (e.g., some or all four pillars 550) in each pillar group 950 may not be next to each other (e.g., may not be adjacent each other).

FIG. 9 also shows a footprint (e.g., layout) 277I, which can represent a footprint of a sensing circuit 277″ associated with a respective pillar group 950. For simplicity, FIG. 9 shows footprints 277I associated with only two sensing circuits 277″. Each sensing circuit 277″ (e.g., shown from a top view) can have a structure similar to (or the same as sensing circuit 277 in FIG. 7A or FIG. 8A). FIG. 9 shows footprint 2271 directly over the location of a respective pillar group 950 as an example. Alternatively, footprint 277I can be at a location different from the location shown in FIG. 9. However, in some structures of a sensing circuit (e.g., sensing circuit 277 or 277″) described herein, placing (e.g., forming) a sensing having a footprint like footprint 277I may allow the memory device (e.g., memory device 200, 800, or 900) described herein to have a relatively small overall footprint for the sensing circuits.

The location and structure of sensing circuit 277 (FIG. 7A and FIG. 8A) allow the memory device described herein (e.g., memory device 200, 800, or 900) to have improvements and benefits over some similar conventional memory devices (e.g., 3D NAND memory devices). For example, the location of sensing circuit 277 allows an accurate sensing of signals (e.g., voltage, current, or both) that may have a relatively small signal value (e.g., current in nanoampere range). This can improve the performance (e.g., during a read operation) of the memory device. The structure of structure sensing circuit 277 is relatively small (compact) and has a relatively small number of transistors (e.g., four transistors T1, T2, T3, and T4). This can allow more room for improvement in components (e.g., increase in tiers of memory cells) that can lead to improvement (e.g., reduction) in the cost of forming the memory device.

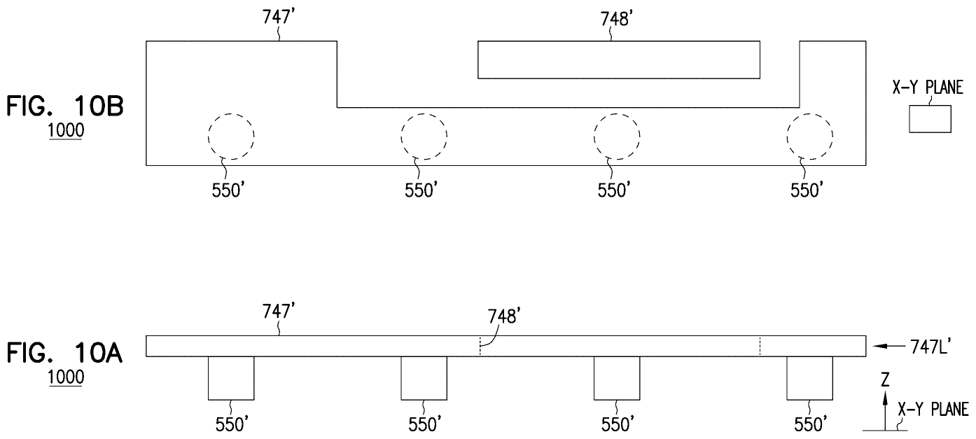

The above description with reference to FIG. 2 through FIG. 9 describes the structure of memory devices 200 and 800, and 900. Some or all of the structures of memory devices 200, 800, and 900 can be formed using processes at least similar to the processes described below with reference to FIG. 10A through FIG. 17B.

FIG. 10A through FIG. 17B show different views of elements during processes of forming a memory device 1000, according to some embodiments described herein. FIG. 10A shows a side view (e.g., cross-section) of a portion of memory device 1000. FIG. 10B shows a top of the portion of memory device 1000 of FIG. 10A. The side view and top view of memory device 1000 in FIG. 10A and FIG. 10B can correspond to the side view and top view of memory device 200 in FIG. 7B and FIG. 7C, respectively. In FIG. 10A through FIG. 17B, for simplicity, some or all labels from one figure (e.g., a preceding figure) may not be shown in another figure (e.g., a succeeding figure).

In FIG. 10A through FIG. 17B, the elements of memory device 100 that are similar to (or the same as) the elements of memory device 200 (FIG. 2 through FIG. 7C) are given labels with the same numerical portions. For example, pillars 550′ of memory device 1000 are similar to or the same as pillars 550 of memory device 200 of FIG. 7A. In another example, conductive region 747′ and 748′ (FIG. 10A and FIG. 10B) are similar to (or the same as) conductive regions 747 and 748 shown in FIG. 7A, FIG. 7B, and FIG. 7C. For simplicity and not to obscure the embodiments (e.g., processes of forming sensing circuit 277 of memory device 1000), the processes of forming pillars 550′ and other portions of memory device 1000 associated with pillars 550′ (e.g., a substrate like substrate 599 and memory cells like memory cells 210, 211, 212, and 213 in FIG. 5) are omitted from the description herein.

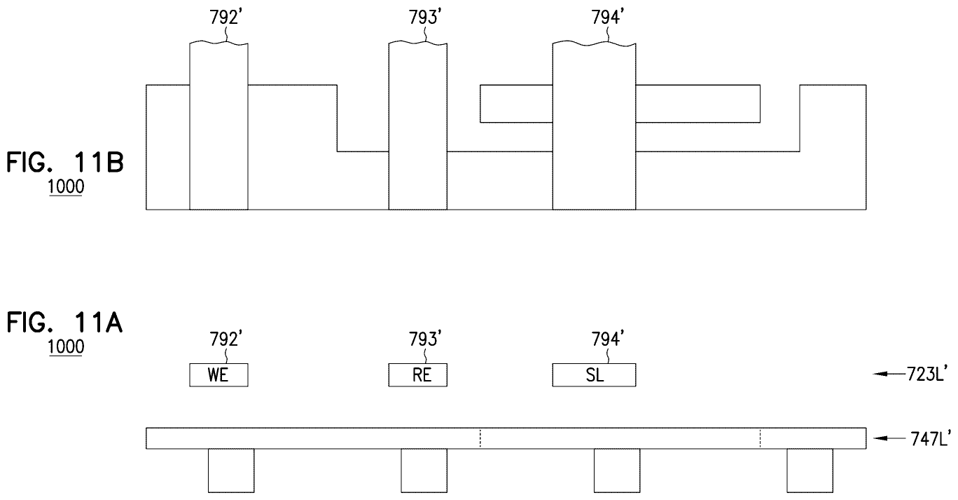

In FIG. 10A, the Z-direction and the X-Y plane (represented by the Z-direction symbol the X-Y plane symbol, respectively) of memory device 1000 are similar to those of memory device 200 shown in FIG. 7A and FIG. 7B. For simplicity, the X-Y plane symbol and the Z-direction symbol in are not repeated in FIG. 11A through FIG. 17B.

In FIG. 10A and FIG. 10B, the process of forming memory device 1000 can include forming a conductive region 747′ and a conductive region 748′ separated from conductive region 747′. Conductive regions 747′ and 748′ can be formed on the same level 747L′ of memory device 1000. Conductive region 747′ can be formed over (e.g., on) pillars (memory cell pillars) 550′ and electrically coupled to (contacting) pillar 550′.

FIG. 11A and FIG. 11B show memory device 1000 after conductive regions 792′, 793′, and 974′ are formed. Forming conductive regions 792′, 793′, and 794′ can include forming (e.g., depositing) a conductive material on a level 723L′ at the locations of conductive regions 792′, 793′, and 974′ of memory device 1000. As shown in FIG. 11A, level 723L′ is above level 747L′ with respect to the Z-direction. Conductive regions 792′, 793′, and 974′ can be associated with signal WE, RE, and SL, respectively.

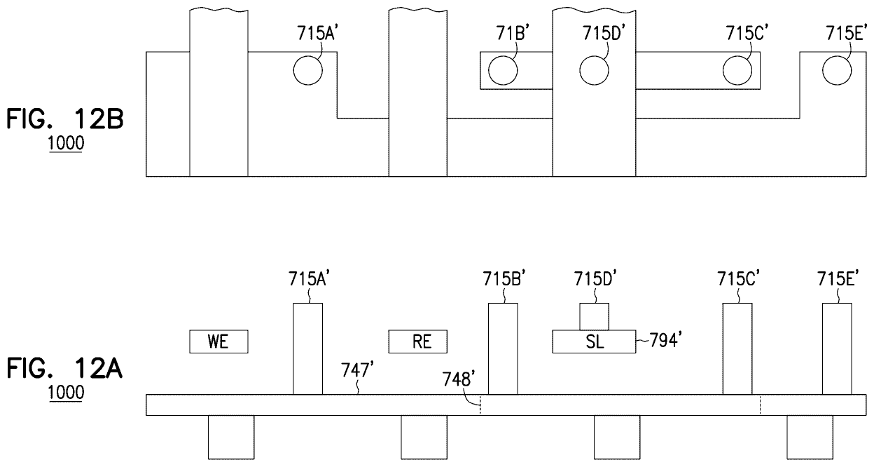

FIG. 12A and FIG. 12B show memory device 1000 after conductive contacts 715A′, 715B′, 715C′, 715D′, and 715E′ are formed over respective conductive regions 747′, 748′, and 794′. Forming conductive contacts 715A′, 715B′, 715C′, 715D′, and 715E′ can include forming conductive pillars (pillars formed from conductive materials) over conductive regions 747′, 748′, 792′, 793′, and 794′.

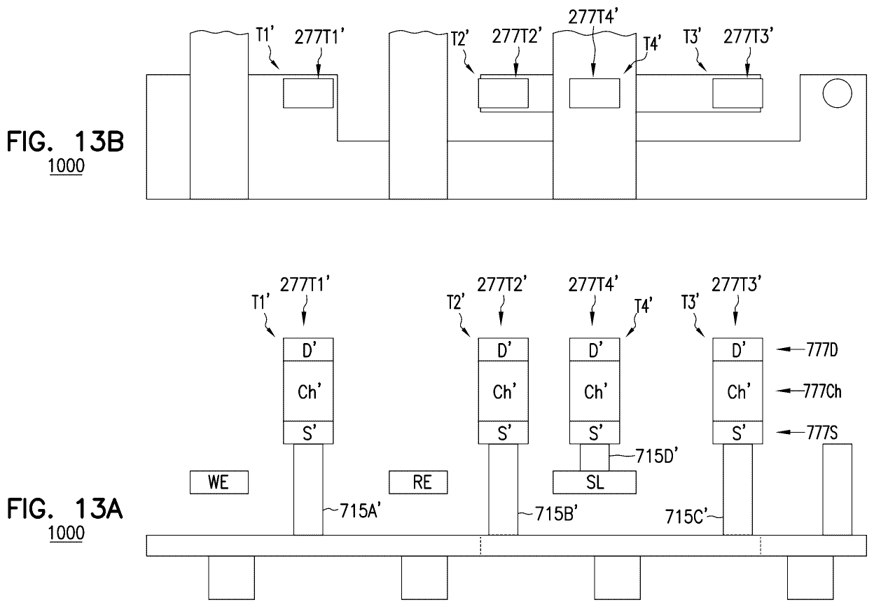

FIG. 13A and FIG. 13B show memory device 1000 after semiconductor structures 277T1′, 277T2′, 277T3′, and 277T4′ are formed over respective conductive contacts 715A′, 715B′, 715C′, and 715D. Forming semiconductor structures 277T1′, 277T2′, 277T3′, and 277T4′ can include forming respective portions associated with terminals D′ and S′ and channel Ch′. As shown in FIG. 13A, portions of semiconductor structures 277T1, 277T2, 277T3, and 277T4 can form respective terminals D′ and S′ and channel Ch′ of transistors T1, T2, T3, and T4. As shown in FIG. 13B, the portions associated with terminals D′ of transistors T1, T2, T3, and T4 can be formed (e.g., located) on the same level 777D of memory device 200. The portions associated with terminals S′ of transistors T1, T2, T3, and T4 can be formed (e.g., located) on the same level 777S of memory device 200. The portions associated with channels Ch′ transistors T1, T2, T3, and T4 can be formed (e.g., located) on the same level 777Ch of memory device 200.

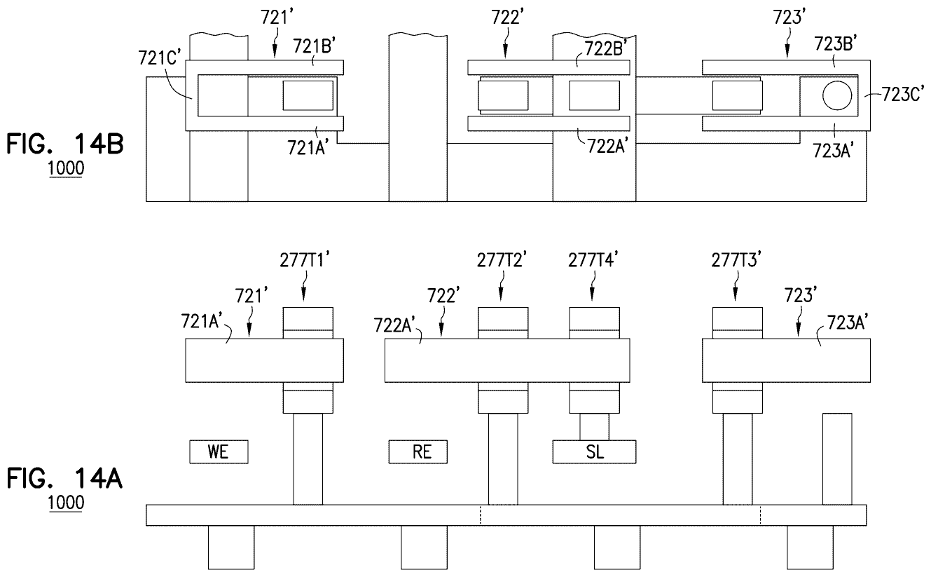

FIG. 14A and FIG. 14B show memory device 1000 after conductive gate structures 721′, 722′, and 723′ are formed. Forming conductive gate structure 721′ can include forming respective conductive regions 721A′, 721B′, and 721C′ on respective sides (e.g., a front side, a back side opposite from the front side, and a left side) of semiconductor structures 277T1. Forming conductive gate structure 722′ can include forming respective conductive regions 722A′ and 722B′ on respective sides (e.g., a front side and a back side opposite from the front side) of semiconductor structures 277T2. Forming conductive gate structure 723′ can include forming respective conductive regions 723A′, 723B′, and 723C′ on respective sides (e.g., a front side, a back side opposite from the front side, and a left side) of semiconductor structures 277T3.

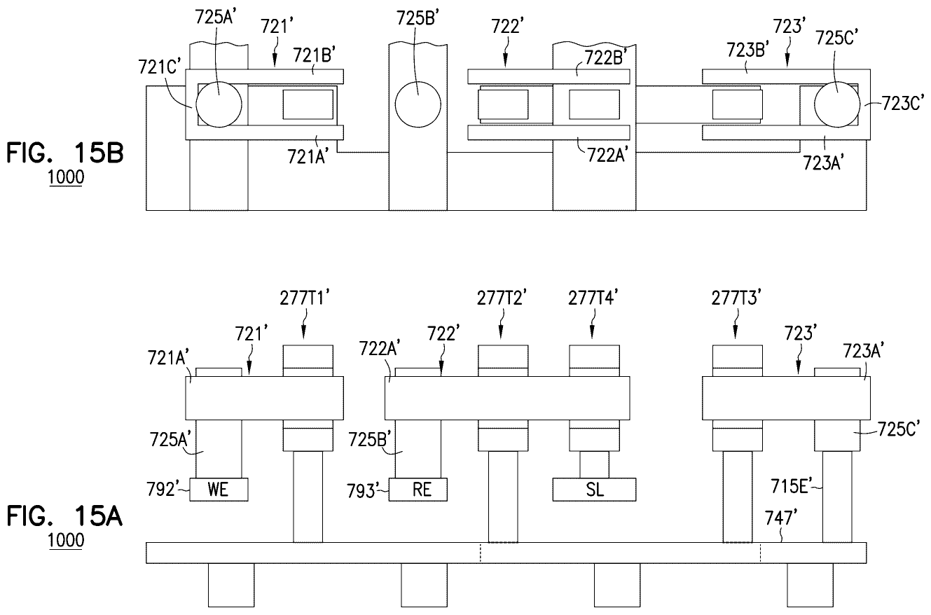

FIG. 15A and FIG. 15B show memory device 1000 after conductive contacts 725A′, 725B′, and 725C′ are formed. Forming conductive contacts 725A′, 725B′, and 725C′ can include forming conductive pillars (pillars formed from conductive materials) over respective conductive regions 792′ and 793′, and conductive contact 715E′. As shown in FIG. 15A and FIG. 15B, conductive contact 725A′ can contact (can be electrically coupled to) conductive gate structure 721′ and conductive region 792′. Conductive contact 725B′ can contact (can be electrically coupled to) conductive gate structure 722′ and conductive region 793′. Conductive contact 725C′ can contact (can be electrically coupled to) conductive gate structure 723′ and conductive region 747′.

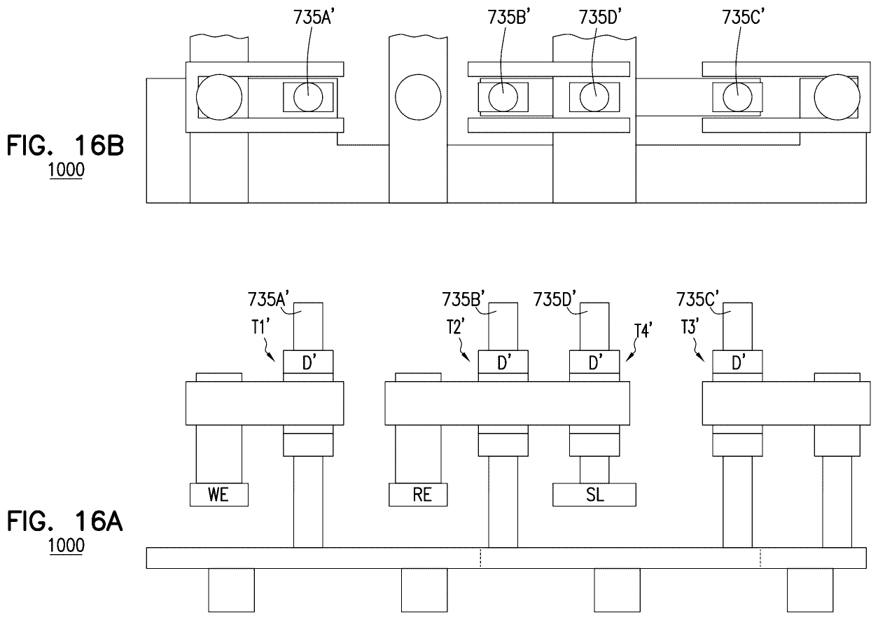

FIG. 16A and FIG. 16B show memory device 1000 after conductive contacts 735A′, 735B′, 735C′, and 735D′ are formed. Forming conductive contacts 735A′, 735B′, 735C′, and 735D′ can include forming conductive pillars (pillars formed from conductive materials) over and form electrical connection with (contact) respective portions of semiconductor structures 277T1, 277T2, 277T3, and 277T4 associated with terminals (e.g., terminals D′) of transistors T1′, T2′, T3′, and T4′.

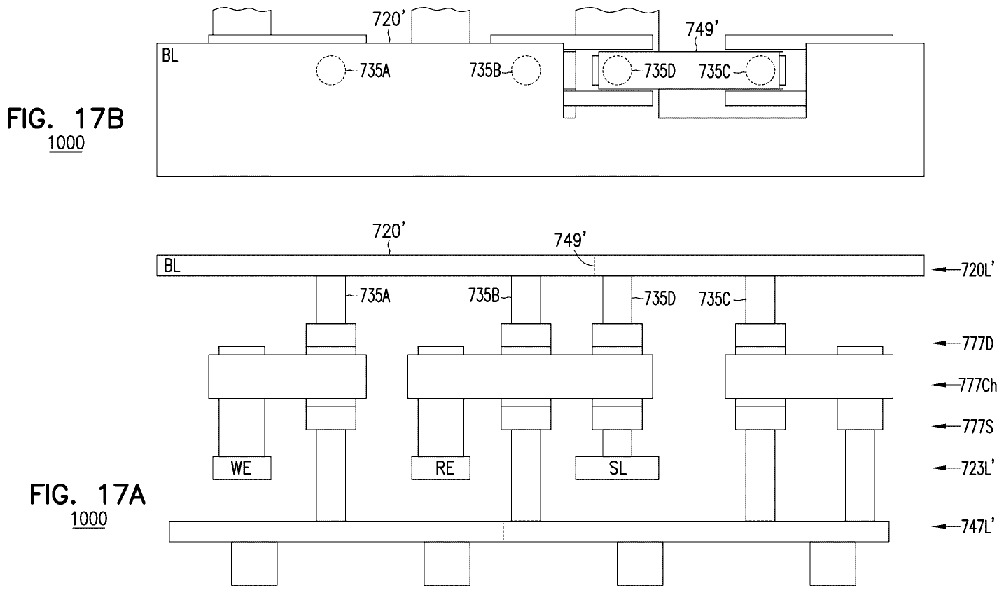

FIG. 17A and FIG. 17B show memory device 1000 after conductive region 720′ and 749′ are formed. Forming conductive regions 720′ and 749′ can include forming (e.g., depositing) a conductive material on a level 720L′ at the locations of conductive regions 720′ and 749′ of memory device 1000. As shown in FIG. 16A, level 720′ is above level 747L′, 723L′, 777S, 777Ch, 777D, with respect to the Z-direction. Conductive region 720′ can be associated with signal BL. As shown in FIG. 17A and FIG. 17B, conductive region 720′ can contact (can be electrically coupled to) conductive contacts 735A′ and 735B′. Conductive region 749′ can contact (can be electrically coupled to) conductive contacts 735C′ and 735D′.

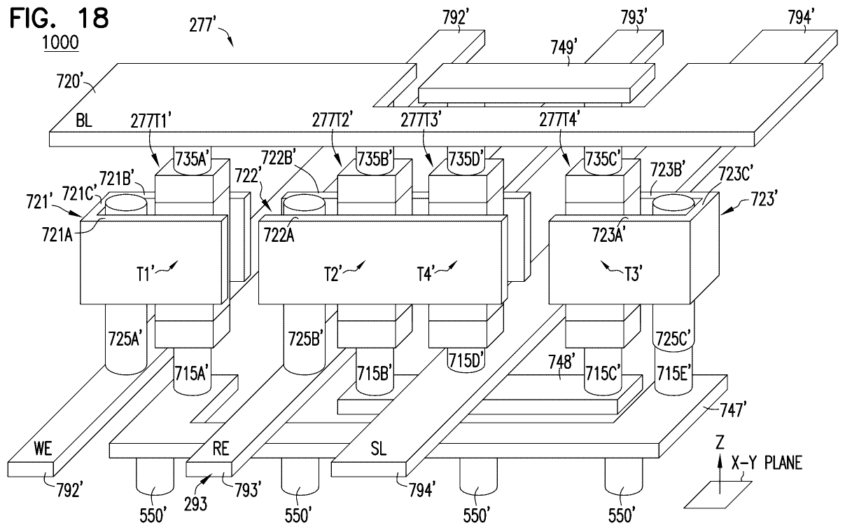

FIG. 18 shows a perspective view (e.g., 3-D view) of the structure of memory device 1000 including the structure of sensing circuit 277′ after the processes associated with FIG. 10A through FIG. 17B are performed. As shown in FIG. 18, memory device 1000 can include elements similar to or the same as the elements of memory device 200 of FIG. 7A. Thus, for simplicity, detailed description of memory device 1000 of FIG. 18 is not described here.

The processes of forming memory device 1000 described above with reference to FIG. 10A through FIG. 18 can include other processes to form a complete memory device (e.g., memory device 1000). Such processes are omitted from the above description so as not to obscure the subject matter described herein. Memory device 1000 can include improvements and benefits similar to those of the memory devices (e.g., memory devices 200, 800, and 900) described above.

The illustrations of apparatuses (e.g., memory devices 100, 200, 800, 900, and 1000) and methods (e.g., method of forming memory device 1000) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 800, 900, and 1000) or a system (e.g., a computer, a cellular phone, or other electronic systems) that includes a device such as any of memory devices 100, 200, 800, 900, and 1000.

Any of the components described above with reference to FIG. 1 through FIG. 18 can be implemented in a number of ways, including simulation via software. Thus, apparatuses, e.g., memory devices 100, 200, 800, 900, and 1000 or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, 800, 900, and 1000 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 18 include apparatuses and methods of forming the apparatuses. One of the apparatuses includes a memory device. The memory device includes: a first conductive region; tiers of memory cells; memory cell pillars extending through the tiers of memory cells; a second conductive region coupled to the memory cell pillars and located between the first conductive region and the tiers of memory cells; semiconductor structures separated from each other and located between the first and second conductive regions, a semiconductor structure among the semiconductor structures including a first portion, a second portion, and a third portion between the first and second portions including a first portion, a second portion, and a third portion between the first and second portions; a first conductive contact located between and contacting the first portion of the semiconductor structure and the first conductive region; and a second conductive contact located between and contacting the second portion of the semiconductor structure and the second conductive region. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a first conductive region;
tiers of memory cells;
memory cell pillars extending through the tiers of memory cells;
a second conductive region coupled to the memory cell pillars and located between the first conductive region and the tiers of memory cells;
semiconductor structures separated from each other and located between the first and second conductive regions, a semiconductor structure among the semiconductor structures including a first portion, a second portion, and a third portion between the first and second portions;
a first conductive contact located between and contacting the first portion of the semiconductor structure and the first conductive region; and
a second conductive contact located between and contacting the second portion of the semiconductor structure and the second conductive region.

2. The apparatus of claim 1, wherein each of the first and second portions of the semiconductor structure includes n-type semiconductor material.

3. The apparatus of claim 1, wherein each of the first and second portions of the semiconductor structure has a higher doping concentration than the third portion of the semiconductor structure.

4. The apparatus of claim 1, wherein:
the first conductive contact includes a first conductive pillar coupled between the first portion of the semiconductor structure and the first conductive region; and
the second conductive contact includes a second conductive pillar coupled between the second portion of the semiconductor structure and the second conductive region.

5. The apparatus of claim 1, wherein the apparatus comprises a memory device, and the conductive region is part of a data line of the memory device.

6. The apparatus of claim 1, further comprising:
a third conductive region between the first conductive region and the second conductive region;
a conductive gate structure adjacent the third portion of the semiconductor structure; and
a conductive pillar located between the first and second conductive regions and coupled to the conductive gate structure.

7. The apparatus of claim 1, further comprising a third conductive region located between the first and second conductive regions, wherein the semiconductor structure is a first semiconductor structure, and the semiconductor structures include:
a second semiconductor structure including a first portion coupled to the first conductive region, a second portion, and a third portion between the first and second portions of the second semiconductor structure;
a third semiconductor structure including a first portion, a second portion coupled to the second portion of the second semiconductor structure, and a third portion between the first and second portions of the third semiconductor structure; and
a fourth semiconductor structure including a first portion coupled to the first portion of the third semiconductor structure, a second portion coupled to the third conductive region, and a third portion between the first and second portions of the fourth semiconductor structure.

8. The apparatus of claim 1, wherein the apparatus comprises a memory device, wherein the semiconductor structure is a first semiconductor structure, and the semiconductor structures include a second semiconductor structure, a third semiconductor structure, and a fourth semiconductor structure, and wherein the first, second, third, and fourth semiconductor structures include respective portions located in a same level of the memory device.

9. The apparatus of claim 8, further comprising:
a first conductive gate structure adjacent the third portion of the first semiconductor structure;
a second conductive gate structure adjacent a portion of each of the second and fourth semiconductor structures;
a third conductive gate structure adjacent a portion of the third semiconductor structure;
a fourth conductive region located between the first and second conductive regions;
a first additional conductive contact located between the first and second conductive regions and coupled to the fourth conductive region;
a fifth conductive region located between the first and second conductive regions;
a second additional conductive contact located between the first and second conductive regions and coupled to the fifth conductive region; and
a third additional conductive contact located between the first and second conductive regions and coupled to the third conductive region.

10. An apparatus comprising:
a data line;
memory cells including associated memory cell pillars;
a first conductive connection coupled to the memory cell pillars;
a first transistor including a first terminal coupled to the data line, a second terminal coupled to the first conductive connection, and a first gate;
a second transistor including a first terminal of the second transistor coupled to the data line, a second terminal of the second transistor, and a second gate;
a third transistor including a first terminal of the third transistor, a second terminal of the third transistor coupled to the second terminal of the second transistor, and a third gate coupled to the first conductive connection;
a fourth transistor including a first terminal coupled to the first terminal of the third transistor, a second terminal, and a fourth gate;
a second conductive connection coupled to the first gate;
a third conductive connection coupled to the second gate and the fourth gate; and
a fourth conductive connection coupled to the first gate.

11. The apparatus of claim 10, wherein:
the data line includes a first conductive region;
the first conductive region includes a second conductive region; and
each of the first, second, third, and fourth transistors includes a semiconductor structure located between the first and second conductive regions.

12. The apparatus of claim 10, wherein:
the data line includes a first conductive region;
the first conductive region includes a second conductive region; and
the second, third, and fourth conductive connections include respective conductive regions located between the first and second conductive regions.

13. The apparatus of claim 10, wherein the first, second, third, and fourth transistors have a same transistor type.

14. The apparatus of claim 10, wherein each of the first, second, third, and fourth transistors includes an enhancement-mode transistor.

15. The apparatus of claim 10, wherein:
the first gate includes a first conductive region adjacent a side of a semiconductor structure of the first transistor;
the second and fourth gates include a second conductive region shared by the second and fourth gates, the second conductive region adjacent a side of a semiconductor structure of the second transistor and a side of a semiconductor structure of the fourth transistor; and
the third gate includes a third conductive region adjacent a side of a semiconductor structure of the third transistor.

16. The apparatus of claim 15, wherein:
the first gate includes a first additional conductive region adjacent an addition side of the semiconductor structure the first transistor;
the second and fourth gates include a second additional conductive region shared by the second and fourth gates, the second additional conductive region adjacent an additional side of the semiconductor structure of the second transistor;
and an additional side of the semiconductor structure of the fourth transistor; and
the third gate includes a third additional conductive region adjacent an additional side of the semiconductor structure the third transistor.

17. A method comprising:
a first conductive region; and located between the first conductive region and the tiers of memory cells;
tiers of memory cells;
memory cell pillars extending through the tiers of memory cells;
forming a first conductive region and a first additional conductive region on a first level of a memory device such that the first conductive region is coupled to memory cell pillars associated with tiers of memory cells;
forming additional conductive regions on a second level of the memory device such that the additional conductive regions are separated from each other;
forming conductive contacts over the first conductive region, the first additional conductive region, and one of the additional conductive regions;
forming semiconductor structures separated from each other such that each of the semiconductor structures is formed over a respective conductive contacts of the conductive contacts, wherein the semiconductor structures are part of transistors of a sensing circuit of the memory device;
forming additional conductive contacts such that each of the additional conductive contacts is over a respective semiconductor structure of the semiconductor structures; and
forming a second conductive region and a second additional conductive region on a third level of a memory device such that the semiconductor structures are between the first and second levels and such that the second conductive region is coupled to first conductive contacts included in the additional conductive contacts, and the second additional conductive region is coupled to second conductive contacts included in the additional conductive contacts.

18. The method of claim 17, wherein forming the forming semiconductor structures includes:
forming respective first portions of the semiconductor structures on a first additional level of the memory device between the second and third levels;
forming respective second portions of the semiconductor structures on a second additional level of the memory device between the second and third levels; and
forming respective third portions of the semiconductor structures on a third additional level of the memory device between the second and third levels.

19. The method of claim 18, wherein the respective first portions of the semiconductor structures and the respective second portions of the semiconductor structures include n-type semiconductor material.

20. The method of claim 17, further comprising:
forming a first conductive gate structure adjacent a portion of the first semiconductor structure;
forming a second conductive gate structure adjacent a portion of each of the second and fourth semiconductor structures; and
a third conductive gate structure adjacent a portion of the third semiconductor structure.
